(19) United States
(12) Patent Application Publication
(10) Pub. No.: US 2026/0213679 A1
(43) Pub. Date: Jul. 23, 2026

(54) ELECTROSTATIC CHUCK MEMBER AND ELECTROSTATIC CHUCK DEVICE

(71) Applicant: SUMITOMO OSAKA CEMENT CO., LTD., Tokyo (JP)

(72) Inventors: Yuuki KINPARA, Tokyo (JP); Satoyoshi INUI, Tokyo (JP); Taku ICHIYOSHI, Tokyo (JP); Toru SUGAMATA, Tokyo (JP)

(73) Assignee: SUMITOMO OSAKA CEMENT CO., LTD., Tokyo (JP)

(21) Appl. No.: 19/142,227

(22) PCT Filed: Dec. 4, 2023
(86) PCT No.: PCT/JP2023/043276

§ 371 Date: Jun. 23, 2025

(30) Foreign Application Priority Data
Dec. 23, 2022 (JP) 2022-206683

(51) Int. Cl. H02N 13/00; H01J 37/32

(52) U.S. Cl. CPC H02N 13/00; H01J 37/32724

(57) ABSTRACT

An electrostatic chuck member including a substrate, and an electrostatic adsorption electrode, in which a side peripheral surface includes at least a first curved surface that is a convex surface provided in a circumferential direction in a peripheral edge portion of the placement surface and a second curved surface provided in the circumferential direction at a different height position from the first curved surface, the substrate has an annular protrusion provided along the peripheral edge portion of the placement surface, an outer edge of the electrostatic adsorption electrode overlaps the annular protrusion in a plan view, at least a part of the first curved surface is provided on an outer peripheral side of the annular protrusion, and a third curved surface that is a convex surface provided in a circumferential direction of an inner periphery is provided on an inner peripheral side of the annular protrusion.

### TECHNICAL FIELD

The present invention relates to an electrostatic chuck member and an electrostatic chuck device.

This application claims priority based on Japanese Patent Application No. 2022-206683 filed on Dec. 23, 2022, the content of which is incorporated herein by reference.

### BACKGROUND ART

In the related art, in a semiconductor manufacturing step of manufacturing a semiconductor device such as IC, LSI, or VLSI, a plate-shaped sample such as a silicon wafer is fixed to an electrostatic chuck member having an electrostatic chuck function by electrostatic adsorption, and a predetermined process is performed thereon. In this step, for example, after fixing the silicon wafer using the electrostatic chuck device, an etching process or a film forming process using plasma is performed on the silicon wafer.

When the electrostatic chuck device is used in the above-described manufacturing step, particulate foreign matter (hereinafter, foreign particles) represented by wafer residues may be formed in the electrostatic chuck member. The foreign particles are charged in a semiconductor manufacturing device and are attached to a surface of the electrostatic chuck device. In the electrostatic chuck device to which the foreign particles that are charged (charged foreign particles) are attached, plasma stability in the manufacturing step deteriorates, and productivity may decrease. In addition, abnormal discharge occurs due to the foreign particles in a plasma step, stabilization of plasma deteriorates, and a decrease in yield of elements or dielectric breakdown of the electrostatic chuck device may occur.

In order to solve the above-described problem, in a manufacturing step of a semiconductor, a process in which an electrostatic chuck device contaminated with foreign particles is cleaned with plasma to remove the foreign particles is performed (for example, refer to Patent Literature No. 1).

### CITATION LIST

### Patent Literature

Patent Literature No. 1: PCT Japanese Translation Patent Publication No. 2013-512564

### SUMMARY OF INVENTION

### Technical Problem

Recently, in order to improve a yield of semiconductor chips obtained from a silicon wafer, a proposal to enlarge an electrostatic adsorption electrode in an electrostatic chuck member has been made. In the electrostatic chuck member where the electrostatic adsorption electrode is enlarged, a difference in adsorption force between a center and a periphery of a wafer placement surface decreases, and the same processing (etching process) as that of a center portion of a silicon wafer can also be performed on an outer peripheral portion of the silicon wafer. As a result, even in the outer peripheral portion of the silicon wafer, a semiconductor chip can be suitably manufactured, and the yield is improved.

On the other hand, when the electrostatic adsorption electrode is enlarged, a distance between a side surface of the electrostatic chuck member and the electrostatic adsorption electrode decreases, and a field intensity of the side surface of the electrostatic chuck member increases. Therefore, the electrostatic chuck member where the electrostatic adsorption electrode is enlarged has a configuration in which charged foreign particles are more likely to be electrostatically adsorbed to the side surface as compared to an electrostatic chuck in the related art.

In the electrostatic chuck member described in Patent Literature No. 1, an inclined portion is provided in the periphery to improve the effect of plasma cleaning. However, in this configuration, cleaning can be effectively performed before wafer processing, but attachment of charged foreign particles to the side surface of the electrostatic chuck member during a manufacturing process is not suppressed. Therefore, there is an issue that a problem such as a decrease in yield of elements (decrease in productivity) or dielectric breakdown of an electrostatic chuck caused by abnormal discharge occurring during wafer processing cannot be sufficiently suppressed. Thus, there is desired an electrostatic chuck member where the effect of the charged foreign particles attached to the side surface of the electrostatic chuck member can be reduced and the occurrence of abnormal discharge can be suppressed even during wafer processing.

The present invention has been made in view of such circumstances, and an object of the present invention is to provide an electrostatic chuck member that can solve a problem caused by the attachment of charged foreign particles to a side surface and that can particularly reduce abnormal discharge occurring during wafer processing. In addition, another object of the present invention is to provide an electrostatic chuck device including such an electrostatic chuck member.

### Solution to Problem

In order to achieve the above-described object, one aspect of the present invention includes the following aspects.
[1] An electrostatic chuck member including a substrate of which one main surface is a placement surface on which a plate-shaped sample is placed, and an electrostatic adsorption electrode provided on a side opposite to the placement surface or in the substrate, in which a side peripheral surface that is continuous with the placement surface in the substrate includes at least a first curved surface that is a convex surface provided in a circumferential direction in a peripheral edge portion of the placement surface and a second curved surface provided in the circumferential direction at a different height position from the first curved surface, the substrate has an annular protrusion provided along the peripheral edge portion of the placement surface, an outer edge of the electrostatic adsorption electrode overlaps the annular protrusion in a plan view, at least a part of the first curved surface is provided on an outer peripheral side of the annular protrusion, and a third curved surface that is a convex surface provided in a circumferential direction of an inner periphery is provided on an inner peripheral side of the annular protrusion.
[2] The electrostatic chuck member according to [1], in which in a plan view, the outer edge is positioned closer to the outer peripheral side with respect to a center of the annular protrusion in a width direction, and a curvature radius of the first curved surface is larger than a curvature radius of the third curved surface.
[3] The electrostatic chuck member according to [2], in which the first curved surface is provided to extend from the annular protrusion to a portion of the substrate below the annular protrusion.
[4] The electrostatic chuck member according to any one of [1] to [3], in which the electrostatic chuck member satisfies following Expressions (A1) and (A2).

[Thickness of Electrostatic Adsorption Electrode]≤[Curvature Radius of First Curved Surface] (A1)

[Thickness of Electrostatic Adsorption Electrode]≤[Curvature Radius of Third Curved Surface] (A2)
[5] The electrostatic chuck member according to any one of [1] to [4], in which a distance from the outer edge to the side peripheral surface is equal to or greater than a distance from an upper surface of the electrostatic adsorption electrode to the placement surface.
[6] The electrostatic chuck member according to any one of [1] to [5], in which a distance from the outer edge to the side peripheral surface is equal to or greater than a distance from an upper surface of the electrostatic adsorption electrode to the placement surface.
[7] An electrostatic chuck device including the electrostatic chuck member according to any one of [1] to [6], and a base member that cools the electrostatic chuck member to adjust a temperature of the electrostatic chuck member.

### Advantageous Effects of Invention

According to the present invention, it is possible to provide an electrostatic chuck member capable of reducing problems caused by the adhesion of charged foreign particles to its side surface. In addition, it is possible to provide an electrostatic chuck device including such an electrostatic chuck member.

### BRIEF DESCRIPTION OF DRAWINGS

FIG. 1 A schematic perspective view showing an example of an electrostatic chuck member 10 of a first embodiment.

FIG. 2 A schematic cross-sectional view showing an example of the electrostatic chuck member 10 of the first embodiment.

FIG. 3 A schematic cross-sectional view showing an example of the electrostatic chuck member 10 of the first embodiment.

FIG. 4 A schematic explanatory view showing an example of a method for manufacturing the electrostatic chuck member 10 according to the first embodiment.

FIG. 5 A schematic explanatory view showing an example of an electrostatic chuck member 20 according to a second embodiment.

FIG. 6 A schematic explanatory view showing an example of an electrostatic chuck member 30 according to a third embodiment.

FIG. 7 A schematic explanatory view showing an electrostatic chuck member 40 according to a modification example of the third embodiment.

FIG. 8 A schematic cross-sectional view showing an example of an electrostatic chuck device of the embodiment.

FIG. 9 A schematic explanatory view showing an example of a semiconductor manufacturing device having the above-described electrostatic chuck device.

### DESCRIPTION OF EMBODIMENTS

### First Embodiment

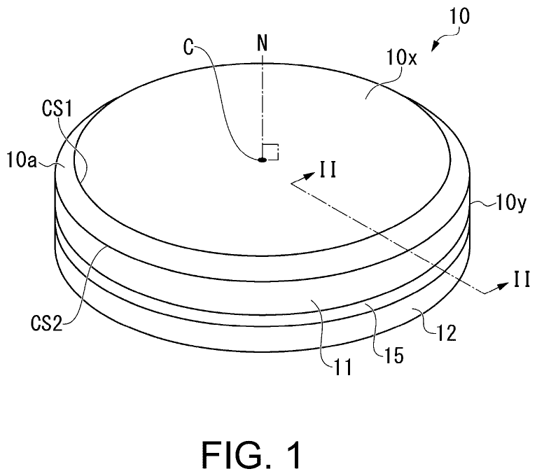

Hereinafter, an example of the electrostatic chuck member according to a first embodiment of the present invention will be described with reference to FIGS. 1 to 4. In all of the following drawings, dimensions, ratios, and the like of the components may be appropriately different from the actual ones in order to easily understand the drawings.

<<Electrostatic Chuck Member>>

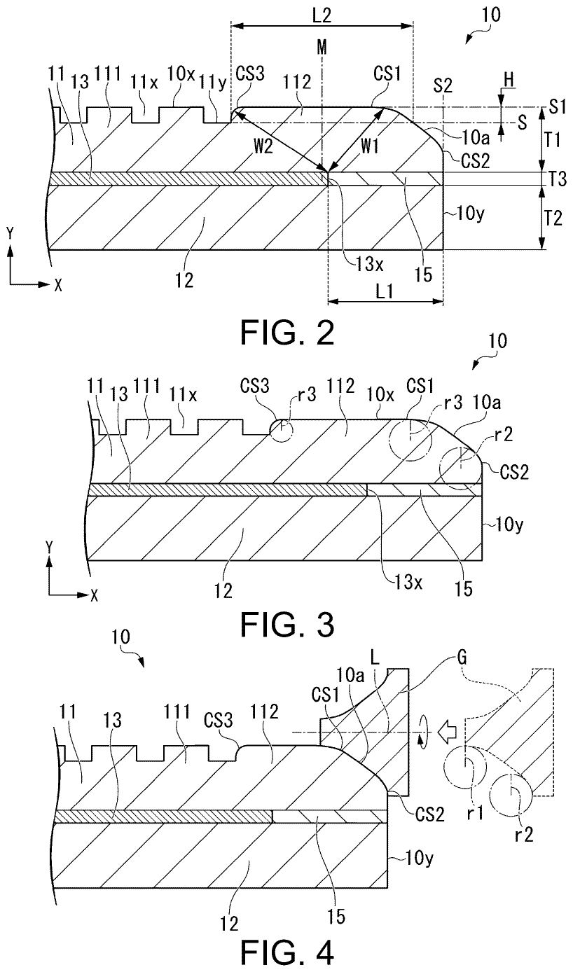

FIG. 1 is a schematic perspective view of an electrostatic chuck member 10 according to a present embodiment. FIGS. 2 and 3 are cross-sectional views showing the electrostatic chuck member 10 of the present embodiment, and are cross-sectional views taken along line II-II of FIG. 1.

As shown in FIGS. 1 to 3, the electrostatic chuck member 10 includes a pair of ceramic plates 11 and 12, and an electrostatic adsorption electrode 13 and an insulating layer 15 interposed between the pair of ceramic plates 11 and 12. In the following description, the electrostatic adsorption electrode will be simply referred to as “electrode”.

A configuration where the pair of ceramic plates 11 and 12 and the insulating layer 15 are combined corresponds to the substrate according to the present invention. One main surface of the substrate is a placement surface 10x on which a plate-shaped sample is placed.

In the following description, the relative position between the members may be described based on an XY axis in which a plane direction of the placement surface 10x is an X direction and a normal direction of the placement surface 10x is a Y direction. In addition, in the Y axis, a side of the electrostatic chuck member 10 closer to the placement surface 10x is referred to as “upper”, and a side of the electrostatic chuck member 10 opposite to the placement surface 10x is referred to as “lower”, and the relative position between the members may be described.

When a minimum circle among circles circumscribing the electrostatic chuck member 10 in a plan view is assumed, the cross-sectional views shown in FIGS. 2 and 3 are cross-sections of the electrostatic chuck member taken along a virtual plane including the center of the circle. In other words, FIGS. 2 and 3 are cross-sectional views showing cross-sections that pass through a center C of the substrate (placement surface 10x) and include a normal line N of the substrate (placement surface 10x). When the electrostatic chuck member 10 is substantially circular in a plan view, the center of the circle and the center of the shape of the electrostatic chuck member in a plan view substantially match each other.

In the present specification, the “in a plan view” refers to a visual field viewed from the Y direction that is a thickness direction of the electrostatic chuck member, or a visual field viewed from a direction of the placement surface 10x.

In addition, assuming that, in a plan view, the minimum circle circumscribes the electrostatic chuck member, the term “sectional view” refers to a field of view in the direction orthogonal to the cross-section obtained by cutting along a virtual plane that is perpendicular to the placement surface and includes the center of the circle.

Furthermore, in a plan view, a side relatively close to the center C may be referred to as “inner”, and a side away from the center C may be referred to as “outer”.

As shown in FIG. 2, a plurality of micro protrusions 111 are provided on an upper surface of the ceramic plate 11. The micro protrusions 111 support the plate-shaped sample in contact with the lower surface of the plate-shaped sample in a case where the plate-shaped sample is placed on the placement surface 10x. The micro protrusions 111 have, for example, a columnar shape or a truncated-conical shape.

A cold gas such as helium (He) for cooling the plate-shaped sample heated during the plasma treatment flows in the space 11x formed around the micro protrusions 111.

In the ceramic plate 11, at the peripheral edge portion of the placement surface 10x (periphery of the micro protrusions 111), an annular protrusion 112 with a rectangular cross-section is provided along the peripheral edge portion so as to encircle the peripheral edge portion. In a case where the plate-shaped sample is placed on the placement surface 10x, the annular protrusion 112 comes into contact with the lower surface of the plate-shaped sample and has a function of sealing the space 11x so that the cold gas flowing in the space 11x does not leak to the outside.

In the present specification, the “annular protrusion 112” is a structure provided on the peripheral edge portion of the placement surface 10x in the ceramic plate 11, and refers to a portion above a virtual plane S that is in contact with the bottom portion 11y between the micro protrusions 111. The virtual plane S is a surface that is in contact with the bottom portion 11y and extends in the X-axis direction. In a case where the height positions of the bottom portions 11y are different at a plurality of positions (the positions in the Y-axis direction are different), an average value is obtained for the height positions of the plurality of bottom portions 11y in the cross-section of the visual field as shown in FIGS. 2 and 3, and a plane that is in contact with the points of the obtained height positions and extends in the X-axis direction is defined as the virtual plane S.

In the electrostatic chuck member including micro protrusions 111 in the one main surface of substrate, a virtual plane in contact with a top of each of the micro protrusions 111 is set as the placement surface 10x. In addition, when the virtual plane set as described above is a recess surface or a protruding surface, a least square plane of the virtual plane is set as the placement surface 10x.

In the electrostatic chuck member 10, the electrode 13 is provided in the substrate, but the present invention is not limited thereto. In the electrostatic chuck member, the electrode 13 may be provided on a side opposite to the placement surface 10x.

The electrostatic chuck member 10 includes a ceramic plate 11, an electrode 13 and an insulating layer 15, and a ceramic plate 12, which are laminated in this order. That is, the electrostatic chuck member 10 is a joined body where the ceramic plate 11 and the ceramic plate 12 are joined and integrated through the electrode 13 and the insulating layer 15. In addition, the electrode 13 and the insulating layer 15 are provided in contact with a joint surface of the ceramic plate 11 facing the ceramic plate 12 and a joint surface of the ceramic plate 12 facing the ceramic plate 11.

### (Ceramic Plate)

The ceramic plates 11 and 12 have the same shape as that of an outer periphery in a plan view.

The ceramic plates 11 and 12 have the same composition or the same major component. The ceramic plates 11 and 12 may be formed of an insulative material or may be formed of a composite of an insulative material and a conductive material.

The insulative material in the ceramic plates 11 and 12 is not particularly limited, and examples thereof include aluminum oxide (Al₂O₃), aluminum nitride (AlN), yttrium oxide (Y₂O₃), yttrium-aluminum-garnet (YAG), and the like. In particular, Al₂O₃ or AlN is preferable.

The conductive material in the ceramic plates 11 and 12 is not particularly limited, and examples thereof include silicon carbide (SiC), titanium oxide (TiO₂), titanium nitride (TiN), titanium carbide (TiC), a carbon material, rare earth oxide, rare earth fluoride, and the like. Examples of the carbon material include carbon nanotubes (CNT) and carbon nanofibers. In particular, SiC is preferable.

The material of the ceramic plates 11 and 12 is not particularly limited as long as it has a volume specific resistance value of about 10¹³ Ω·cm or more and 10¹⁷ Ω·cm or less, has a mechanical strength, and has durability to corrosive gas and plasma thereof. Examples of the material include an Al₂O₃ sintered compact, an AlN sintered compact, an Al₂O₃—SiC composite sintered compact, and the like. From the viewpoints of dielectric characteristics, high corrosion resistance, plasma resistance, and heat resistance at a high temperature, it is preferable that the material of the ceramic plates 11 and 12 is an Al₂O₃—SiC composite sintered compact.

An average primary particle diameter of the insulative material forming the ceramic plates 11 and 12 is preferably 0.5 μm or more and 3.0 μm or less, more preferably 0.7 μm or more and 2.0 μm or less, and still more preferably 1.0 μm or more and 2.0 μm or less.

When the average primary particle diameter of the insulative material forming the ceramic plates 11 and 12 is 0.5 μm or more and 3.0 μm or less, the ceramic plates 11 and 12 that are dense, have high voltage endurance, and have high durability can be obtained.

A method of measuring the average primary particle diameter of the insulative material forming the ceramic plates 11 and 12 is as follows. Using a field emission scanning electron microscope (FE-SEM; manufactured by JEOL Ltd., JSM-7800F-Prime), a cut surface of the ceramic plates 11 and 12 in the thickness direction is observed at a magnification of 10000-fold, and an average particle diameter of 200 particles of the insulative material is obtained as the average primary particle diameter using an intercept method.

### (Electrostatic Adsorption Electrode)

The electrode 13 is used to generate charges and fix a plate-shaped sample using an electrostatic adsorption force. In addition, the electrode 13 is a thin electrode that is wider in a direction orthogonal to the thickness direction than in the thickness direction. The electrode 13 can be formed by applying and sintering a paste for formation of electrode layer. The thickness of the obtained electrode 13 can be controlled by acquiring in advance a correspondence between the coating thickness of the paste for formation of electrode layer and the thickness of the obtained electrode 13 through a preliminary experiment to adjust the coating thickness of the paste for formation of electrode layer.

The electrode 13 is formed of a sintered compact of particles of a conductive material or a composite (sintered compact) of particles of an insulating ceramic and particles of a conductive material.

When the electrode 13 is formed of the insulating ceramic and the conductive material, a volume specific resistance value of a mixed material of the insulating ceramic and the conductive material is preferably about 10⁻⁶ Ω·cm or more and 10⁻² Ω·cm or less.

When the electrode 13 is formed of a composite of the insulating ceramic and the conductive material, the content of the conductive material in the electrode 13 is preferably 15% by mass or more and 100% by mass or less and more preferably 20% by mass or more and 100% by mass or less. When the content of the conductive material is the lower limit value or more, sufficient dielectric characteristics can be exhibited in the ceramic plate 12.

The conductive material in the electrode 13 may be a conductive ceramic or a conductive material such as a metal or a carbon material. The conductive material in the electrode 13 is preferably at least one selected from the group consisting of SiC, TiO₂, TiN, TiC, tungsten (W), tungsten carbide (WC), molybdenum (Mo), molybdenum carbide (Mo₂C), tantalum (Ta), tantalum carbide (TaC, Ta₄C₅), a carbon material, and a conductive composite sintered compact.

Examples of the carbon material include carbon black, carbon nanotubes, carbon nanofibers, and the like.

Examples of the conductive composite sintered compact include Al₂O₃—Ta₄C₅, Al₂O₃—W, Al₂O₃—SiC, AlN—W, AlN—Ta, and the like.

The conductive material in the electrode 13 is formed of at least one selected from the group consisting of the above-described materials such that the conductivity of the electrode can be secured.

The insulating ceramic in the electrode 13 is not particularly limited and is preferably, for example, at least one selected from the group consisting of Al₂O₃, AlN, silicon nitride (Si₃N₄), Y₂O₃, YAG, samarium-aluminum oxide (SmAlO₃), magnesium oxide (MgO), and silicon oxide (SiO₂).

The electrode 13 is formed of the conductive material and the insulative material such that a joint strength of the ceramic plates 11 and 12 and the electrode 13 is improved. In addition, the electrode 13 is formed of the conductive material and the insulative material such that a mechanical strength as an electrode increases.

The insulative material in the electrode 13 is Al₂O₃ such that dielectric characteristics, high corrosion resistance, plasma resistance, and heat resistance at a high temperature are maintained.

A ratio (mixing ratio) between the contents of the conductive material and the insulative material in the electrode 13 is not particularly limited and is appropriately adjusted depending on the use of the electrostatic chuck member 10.

The outer edge 13x of the electrode 13 overlaps the annular protrusion 112 in a plan view. As shown in FIG. 2, in the electrostatic chuck member 10, the outer edge 13x is positioned outside the center (represented by a reference numeral M) of the annular protrusion 112 in the width direction (X direction).

### (Insulating Layer)

The insulating layer 15 is configured to be provided to join the ceramic plates 11 and 12 to each other at a position between the ceramic plate 11 and the ceramic plate 12 other than a portion where the electrode 13 is formed. The insulating layer 15 is disposed around the electrode 13 in a plan view between the ceramic plate 11 and the ceramic plate 12 (between the pair of ceramic plates).

The shape of the insulating layer 15 (the shape of the insulating layer 15 when seen in a plan view) is not particularly limited and is appropriately adjusted depending on the shape of the electrode 13. The thickness of the insulating layer 15 (the width in the Y direction) is the same as the thickness of the electrode 13.

The insulating layer 15 may be formed of an insulative material or may be formed of a composite of an insulative material and a conductive material. The volume specific resistance value of the insulating layer 15 is 10¹³ Ω·cm or more and 10¹⁷ Ω·cm or less.

The insulative material forming the insulating layer 15 is not particularly limited and is preferably the same as the major component of the ceramic plates 11 and 12. The insulative material forming the insulating layer 15 is, for example, preferably at least one selected from the group consisting of Al₂O₃, AlN, Si₃N₄, Y₂O₃, YAG, SmAlO₃, MgO, and SiO₂. The insulative material forming the insulating layer 15 is preferably Al₂O₃. The insulative material forming the insulating layer 15 is Al₂O₃ such that dielectric characteristics, high corrosion resistance, plasma resistance, and heat resistance at a high temperature are maintained.

The conductive material forming the insulating layer 15 is not particularly limited and is preferably the same as the major component of the ceramic plates 11 and 12. The conductive material forming the insulating layer 15 is, for example, preferably at least one selected from the group consisting of SiC, TiO₂, TiN, TiC, W, WC, Mo, Mo₂C, and a carbon material. Examples of the carbon material include carbon nanotubes, carbon nanofibers, and the like. The conductive material forming the insulating layer 15 is preferably SiC.

The content of the insulative material in the insulating layer 15 is preferably 80% by mass or more and 96% by mass or less, more preferably 80% by mass or more and 95% by mass or less, and still more preferably 85% by mass or more and 95% by mass or less. When the content of the insulative material is the lower limit value or more, sufficient voltage endurance can be obtained. When the content of the insulative material is the upper limit value or less, the static elimination effect of the conductive material in the insulating layer 15 can be sufficiently exhibited.

The content of the conductive material in the insulating layer 15 is preferably 4% by mass or more and 20% by mass or less, more preferably 5% by mass or more and 20% by mass or less, and still more preferably 5% by mass or more and 15% by mass or less. When the content of the conductive material is the lower limit value or more, the static elimination effect of the conductive material can be sufficiently exhibited. When the content of the conductive material is the upper limit value or less, a sufficient withstand voltage can be obtained.

The average primary particle diameter of the insulative material forming the insulating layer 15 is preferably 0.5 μm or more and 3.0 μm or less and more preferably 0.7 μm or more and 2.0 μm or less.

When the average primary particle diameter of the insulative material forming the insulating layer 15 is 0.5 μm or more, sufficient voltage endurance can be obtained. On the other hand, when the average primary particle diameter of the insulative material forming the insulating layer 15 is 3.0 μm or less, processing such as grinding is simple.

The average primary particle diameter of the conductive material forming the insulating layer 15 is preferably 0.1 μm or more and 1.0 μm or less and more preferably 0.1 μm or more and 0.8 μm or less.

When the average primary particle diameter of the conductive material forming the insulating layer 15 is 0.1 μm or more, sufficient voltage endurance can be obtained. On the other hand, when the average primary particle diameter of the conductive material forming the insulating layer 15 is 1.0 μm or less, processing such as grinding is simple.

A method for measuring the average primary particle diameters of the insulative material and the conductive material forming the insulating layer 15 is the same as the method for measuring the average primary particle diameters of the insulative material and the conductive material forming the ceramic plates 11 and 12.

The insulating layer 15 may be provided separately from the ceramic plates 11 and 12, or may be integrally formed with any one of the ceramic plates 11 and 12 and subsequently joined to another one of the ceramic plates.

In the present specification, “being integrally formed with” represents being formed as one member (being one member). In this sense, the configuration where “being integrally formed with any one of the ceramic plates 11 and 12” is, for example, different from the configuration where the ceramic plate 11 and the insulating layer 15 that are originally two members are “integrated” into one member. The member where the ceramic plate and the insulating layer are integrally formed can be formed by grinding or polishing one surface of the ceramic plate (the ceramic plate not including a recess portion) as the material to be concave.

Further, the insulating layer 15 may be configured to be integrally formed with both of the ceramic plates 11 and 12.

The electrostatic chuck member where both of the ceramic plates 11 and 12 and the insulating layer are integrally formed can be formed using the following method.

For example, preforms that have the same shape as the ceramic plates 11 and 12 and have yet to be sintered are formed using raw material powder (for example, alumina powder or SiC powder) of inorganic particles as a raw material of the ceramic plate, a conductive paste is applied to one of the obtained preforms by screen printing, and another preforms is stacked thereon to obtain a stacked body. Next, by hot-pressing and calcinating the stacked body, the electrostatic chuck member where both of the ceramic plates 11 and 12 and the insulating layer are integrally formed is obtained.

The above-described preforms may be press-formed, may be formed by casting the paste of the raw material powder into a mold, or may be formed by forming thin green sheets using the raw material powder of the inorganic particles and stacking the green sheets.

The thickness of the obtained electrode 13 can be controlled by acquiring in advance a correspondence between the coating thickness of the paste for formation of electrode layer and the thickness of the obtained electrode 13 through a preliminary experiment to adjust the coating thickness of the paste for formation of electrode layer.

### (Shape of Electrostatic Chuck Member)

Next, the shape of the electrostatic chuck member 10 will be described with reference to FIGS. 2 and 3. In the following description, it is assumed that the thickness of the ceramic plate 11 is “thickness T1”, the thickness of the ceramic plate 12 is “thickness T2”, and the thickness of the electrode 13 is “thickness T3”. Further, a distance in the X direction from the outer edge 13x of the electrode 13 to the side peripheral surface 10y is referred to as a “width L1”, and a distance in the X direction of the annular protrusion 112 is referred to as a “width L2”.

The thickness T1 of the ceramic plate 11 and the thickness T2 of the ceramic plate 12 are appropriately set depending on performance of an electrostatic chuck device or a semiconductor manufacturing device where the electrostatic chuck member 10 is adopted. For example, the thickness T1 is preferably 100 μm or more and 900 μm or less and more preferably 400 μm or more and 600 μm or less. In addition, the thickness T2 may largely vary depending on whether or not an additional internal electrode, heater, or the like formed in the lower ceramic plate is present, and is selected as, 0.9 mm or more and 4 mm or less, or the like. However, the thickness T2 is not limited to the example.

The thickness T3 of the electrode 13 is appropriately set depending on performance of an electrostatic chuck device or a semiconductor manufacturing device where the electrostatic chuck member 10 is adopted. For example, the thickness T3 is preferably 5 μm or more and 40 μm or less and more preferably 10 μm or more and 20 μm or less.

The width L1 is preferably 500 μm or more and 2000 μm or less. In addition, the width L2 of the annular protrusion 112 is preferably 500 μm or more and 3500 μm or less.

The width L1 may satisfy L1<L2 in order to effectively obtain the adsorption force of the wafer adsorbed to the annular protrusion 112. For example, in a case where the width L2 is 3500 μm, the width L1 can be 1800 μm, and in a case where the width L2 is 2000 μm, the width L1 can be 700 μm.

A side peripheral surface 10y that is continuous to the placement surface 10x in the substrate of the electrostatic chuck member 10 includes at least a first curved surface CS1 that is provided in a circumferential direction in a peripheral edge portion of the placement surface 10x, and a second curved surface CS2 that is provided in the circumferential direction at a different height position from the first curved surface CS1. Both of the first curved surface CS1 and the second curved surface CS2 of the electrostatic chuck member 10 are convex surfaces.

In addition, at least a part of the first curved surface CS1 is provided on the annular protrusion 112. In other words, at least a part of the first curved surface CS1 is provided on the outer peripheral side of the annular protrusion 112.

Further, in the side peripheral surface 10y of the electrostatic chuck member 10, an inclined surface 10a exposed to a field of view from a direction of the placement surface 10x is provided between the first curved surface CS1 and the second curved surface CS2. That is, the side peripheral surface 10y includes the first curved surface CS1, the inclined surface 10a, and the second curved surface CS2 in order from the placement surface 10x side.

In the present specification, “convex surface” refers to a convex curved surface in a +y direction in a cross-sectional view in the side peripheral surface.

On the other hand, “inclined surface” refers to a surface having a fixed inclination in a cross-sectional view in the side peripheral surface.

The inclined surface 10a is a surface obtained by linearly chamfering corner portions along a virtual plane S1 and a virtual plane S2. Further, at both ends of the inclined surface 10a in a field of view of FIG. 2, two new corner portions obtained by chamfering are processed into the first curved surface CS1 and the second curved surface CS2 that are outwardly convex curved surfaces (convex surfaces).

It is preferable that each of a curvature radius r1 of the first curved surface CS1 and a curvature radius r2 of the second curved surface CS2 is equal to or more than the thickness T3 of the electrode 13. By setting the curvature radii of the first curved surface CS1 and the second curved surface CS2 to be more than the thickness T3 of the electrode 13, concentration of an electric field in the first curved surface CS1 and the second curved surface CS2 during a plasma treatment can be suppressed, and concentration of fixation of charged foreign particles to a specific portion (for example, a corner portion) can be suppressed.

The curvature radii of the first curved surface CS1 and the second curved surface CS2 relate to a shape formed as a result of grinding or polishing the substrate of the electrostatic chuck member 10. The conductive material and the insulative material forming the substrate include particles having a particle diameter more than the curvature radii of the first curved surface CS1 and the second curved surface CS2, and a shape or a particle diameter of the particles changes by grinding or polishing even when disposed in the first curved surface CS1 or the second curved surface CS2. Therefore, the curvature radii of the first curved surface CS1 and the second curved surface CS2 do not depend on the particle diameter of the material of the substrate.

The curvature radius r1 of the first curved surface CS1 and the curvature radius r2 of the second curved surface CS2 are obtained using the following method.

First, when a minimum circle among circles perpendicular to the placement surface and circumscribing the electrostatic chuck member in a plan view is assumed, a measured portion (convex surface) of the electrostatic chuck member is cut along a virtual plane including a center of the circle. The cross-section may be ground with a grindstone having a grain size of 1000 or more.

Next, the enlarged photograph of the obtained cross-section is obtained. The magnification is set according to the size of the convex surface obtained by measuring and observing the convex surface using a stereoscope. The magnification is a magnification where the curvature radii can be appropriately measured from the obtained photograph, and can be appropriately selected in a range of, for example, 40-fold to 200-fold.

The curvature radii r1 and r2 of the convex surface are measured from the obtained enlarged photograph.

The above-described measurement method is also used for measuring a curvature radius of a concave surface described below.

In the electrostatic chuck member 10, the first curved surface CS1 and the second curved surface CS2 may be formed in a part of the side peripheral surface 10y in the circumferential direction, or the first curved surface CS1 and the second curved surface CS2 may be formed in the entire area in the circumferential direction. In addition, the curvatures of the first curved surface CS1 and the second curved surface CS2 may be fixed in the circumferential direction or may vary in the circumferential direction.

It is considered that the amount of charged foreign particles attached to the side peripheral surface 10y increases by enlarging the electrode 13 and decreasing a distance (width L1) in the X direction from an outer edge 13x of the electrode 13 to the side peripheral surface 10y. Due to the recent enlargement of the electrode 13, the width L1 is required to be 1 mm or less (1000 μm or less).

In addition, it is preferable that the distance (width L1) from the outer edge 13x to the side peripheral surface 10y is equal to or greater than the distance (thickness T1 of the ceramic plate 11) from the upper surface of the electrode 13 to the placement surface 10x (T1≤L1). As a result, the dielectric breakdown on the side peripheral surface 10y side can be suppressed.

In this case, in a relationship with the thickness T1 of the ceramic plate 11, the width L1 is required to be equal to or less than twice the thickness T1 (L1/T1≤2). By decreasing the width L1 as described above, the charged foreign particles are likely to be attached to the side peripheral surface 10y.

Regarding this point, as a result of investigating the configuration of the electrostatic chuck member, the present inventors thought that the attachment of the charged foreign particles to the side peripheral surface 10y can be suppressed by adopting a structure where concentration of an electrostatic field that causes the attachment of the charged foreign particles is suppressed.

In the electrostatic chuck member in the related art, an upper portion of a side peripheral surface is a corner portion. In addition, when the upper portion of the peripheral side surface is chamfered as in the electrostatic chuck member described in Patent Literature No. 1, two corner portions are formed in the side peripheral surface. Such a corner portion has a point (apex) at which two straight lines (planar surfaces) are in contact with each other when viewed from a cross-section. On the other hand, the electrostatic field for adsorbing the plate-shaped sample is likely to concentrate on the corner portions of the side peripheral surface, and a large amount of the charged foreign particles attracted by the electrostatic field are likely to be strongly attached to narrow ranges around the corner portions of the side peripheral surface.

On the other hand, when the corner portions are curved to form the first curved surface CS1 and the second curved surface CS2 as in the electrostatic chuck member 10, the above-described electrostatic field is dispersed in the first curved surface CS1 and the second curved surface CS2 and is difficult to concentrate on a specific portion. As a result, the adhesion points of the charged foreign particles are dispersed, the number of charged foreign particles per unit surface area is reduced, and thus it is easy to suppress the abnormal discharge.

In addition, when the corner portions are curved, the areas of the formed first curved surface CS1 and the formed second curved surface CS2 are less than the area of a surface from an end portion of the placement surface 10x to a lower end of the second curved surface CS2 through the virtual plane S1 and the virtual plane S2, that is, a surface that is present when the corner portions are not curved. As described above, since the charged foreign particles are likely to be attached to the corner portions of the electrostatic chuck member, when the corner portions are curved, the surface area of portions where the charged foreign particles can be attached can be reduced. Therefore, this configuration is suitable as a configuration where abnormal discharge is suppressed.

Further, a third curved surface CS3 that is a convex surface provided in the circumferential direction of the annular protrusion 112, is provided on the inner peripheral side of the annular protrusion 112.

In the electrostatic chuck member 10, the outer edge 13x of the electrode 13 overlaps the annular protrusion 112 in a plan view. In addition, in a case where the electric field is applied to the electrode 13 during the plasma treatment, the electric field is likely to be concentrated on the outer edge 13x of the electrode 13. Therefore, in a case where the annular protrusion 112 has corners, the electric field concentrated on the outer edge 13x during the plasma treatment is likely to be concentrated on the corners of the annular protrusion 112, and the charged foreign particles are likely to be attached to the corners.

In contrast, in the annular protrusion 112, not only the first curved surface CS1 provided on the outer peripheral side but also the third curved surface CS3, which is a convex surface, is provided on the inner peripheral side, and corners where the electric field is likely to be concentrated are removed. Therefore, it is possible to suppress the concentration of fixation of the charged foreign particles to the annular protrusion 112 during the plasma treatment.

Further, as shown in FIG. 2, in a case where the outer edge 13x is positioned outside the center of the annular protrusion 112 in the width direction, the curvature radius r1 of the first curved surface CS1 may be larger than the curvature radius r3 of the third curved surface CS3.

In a case where the outer edge 13x is positioned outside, a distance W1 from the outer edge 13x to the first curved surface CS1 is shorter than a distance W3 from the outer edge 13x to the third curved surface CS3. In this case, in a case where the first curved surface CS1 and the third curved surface CS3 are compared with each other, the electric field is concentrated on the first curved surface CS1 more than on the third curved surface CS3. Therefore, by making the curvature radius r1 larger than the curvature radius r3, the electric field can be easily dispersed in the first curved surface CS1, and the concentration of fixation of the charged foreign particles can be effectively suppressed.

Furthermore, the first curved surface CS1 may be provided to extend from the annular protrusion 112 to the ceramic plate 11 positioned below the annular protrusion 112. In this case, the curvature radius r1 is larger than the height H of the annular protrusion 112. In this case, it is easy to configure the curvature radius r1 to be larger than the curvature radius r3, which is preferable.

It is preferable that the curvature radius r1 of the first curved surface CS1 and the curvature radius r3 of the third curved surface CS3 are each equal to or greater than the thickness T3 of the electrode 13 (satisfy following Expressions (A1) and (A2)).

[Thickness T3 of Electrostatic Adsorption Electrode]≤[Curvature Radius r1 of First Curved Surface CS1] (A1)

[Thickness T3 of Electrostatic Adsorption Electrode]≤[Curvature Radius r3 of Third Curved Surface CS3] (A2)

A curvature radius r3 of the third curved surface CS3 is preferably equal to or more than the thickness T3 of the electrode 13. By making the curvature radius r3 larger than the thickness T3, it is possible to suppress the concentration of the electric field at the third curved surface CS3 during the plasma treatment, and it is possible to suppress the concentration of fixation of the charged foreign particles.

The curvature radius of the third curved surface CS3 does not depend on the particle diameter of the material of the substrate, similarly to the curvature radii of the first curved surface CS1 and the second curved surface CS2.

The curvature radius r3 of the third curved surface CS3 is obtained in the same manner as the curvature radii of the first curved surface CS1 and the second curved surface CS2.

In the electrostatic chuck member 10, the third curved surface CS3 may be formed in a part of the inner peripheral side of the annular protrusion 112 in the circumferential direction, or the third curved surface CS3 may be formed in the entire circumferential direction. In addition, the curvature of the third curved surface CS3 may be fixed in the circumferential direction or may vary in the circumferential direction.

In a case where the outer edge 13x is positioned at the center of the annular protrusion 112 in the width direction, the curvature radius r1 of the first curved surface CS1 and the curvature radius r3 of the third curved surface CS3 may coincide with each other.

### (Surface Roughness)

It is preferable that the first curved surface CS1, the second curved surface CS2, and the third curved surface CS3 each have an arithmetic average roughness Ra of 2 μm or less. Since the arithmetic average roughness Ra of the first curved surface CS1, the second curved surface CS2, and the third curved surface CS3 is 2 μm or less, it is possible to reduce the charged foreign particles attached to the first curved surface CS1, the second curved surface CS2, and the third curved surface CS3, and it is possible to efficiently suppress the above-described defect.

The arithmetic average roughness Ra can be measured using a surface roughness/contour shape measuring machine (SURCOM NEX200, manufactured by Tokyo Seimitsu Co., Ltd.). Specifically, regarding the first curved surface CS1 and the second curved surface CS2, the same measurement is performed at four positions at intervals of 90° in the circumferential direction when the electrostatic chuck member 10 is seen in a plan view. Regarding the measured values of the arithmetic average roughness Ra obtained at the four positions in the circumferential direction, an average value is calculated as the arithmetic average roughness Ra.

In the electrostatic chuck member adopted in the electrostatic chuck device in the related art, the placement surface is mirror-finished such that Ra is about 0.05 μm and suitably about 0.01 to 0.02 μm. In the electrostatic chuck member where micro protrusions are provided on the placement surface, Ra of a tip of the micro protrusion may satisfy the above-described Ra.

On the other hand, in the electrostatic chuck member in the related art, the side peripheral surface is finished to be rougher than the placement surface such that Ra is about a surface accuracy of 3 to 4 μm. The reason for this is that, during the manufacturing of the electrostatic chuck member, the processing accuracy of the placement surface in direct contact with a wafer has attracted attention, whereas the side peripheral surface on which the plate-shaped sample is not placed has not been focused on. Therefore, in the electrostatic chuck member in the related art, polishing on the side peripheral surface is minimized in consideration of the production efficiency. However, the present inventors achieved an idea that, when Ra of the side peripheral surface is a surface accuracy of about 3 to 4 μm, the surface area where the charged foreign particles can be attached is very wide, the charged foreign particles are more likely to be adsorbed by an internal electrode close to the side peripheral surface, and a larger amount of charged foreign particles are likely to remain.

Accordingly, the present inventors conceived simple and effective means where in the electrostatic chuck member 10, the structure where the first curved surface CS1 and the second curved surface CS2 in the side peripheral surface 10y are smoother than that in the related art at 2 μm or less such that the surface area where the charged foreign particles can be adsorbed is reduced is adopted, and Ra of the side peripheral surface 10y is reduced to half of that in the related art such that the amount of charged foreign particles attached to and remaining in the side peripheral surface can be significantly reduced to half or less of that in the related art.

Typically, it is assumed that adsorption and desorption of the charged foreign particles to and from the surface of the electrostatic chuck member are repeated during wafer processing. Here, it is assumed that in a case where the amount of the charged foreign particles attached per unit surface area increases, the charged foreign particles are adsorbed to and desorbed from the surface of the electrostatic chuck member as agglomerates in which a plurality of charged foreign particles are aggregated. In a case where such agglomerates are adsorbed to and desorbed from the surface of the electrostatic chuck member, it is considered that “abnormal discharges,” which impair plasma stability for the first time and reduce the yield of the manufactured elements, occur.

That is, in the semiconductor manufacturing device, in a case where the charged foreign particles are attached to the side peripheral surface of the electrostatic chuck member during the wafer processing, abnormal discharge does not occur at all until the amount of the charged foreign particles attached per unit surface area thereof is increased to form the agglomerate, and the abnormal discharge occurs only in a case where the amount of the charged foreign particles attached per unit surface area thereof exceeds the threshold value at which the agglomerate is formed. In such a case, in a case where the amount of the charged foreign particles attached is reduced, for example, to less than the threshold value, the amount of abnormal discharge can be significantly suppressed, and a high effect can be expected. “The threshold” is affected by various conditions such as the configuration of the semiconductor manufacturing device, the kind of the wafer, and wafer processing conditions.

That is, since it is considered that the amount of the charged foreign particles attached and the number of occurrences of the abnormal discharge are not in a linear relationship but in a correspondence relationship having a threshold value, the inventors have come to the idea that the occurrence of the abnormal discharge is expected to be significantly suppressed by a simple means of reducing the Ra of the side peripheral surface 10y by half as compared with the related art.

The Ra of the first curved surface CS1 and the second curved surface CS2 is preferably 1.5 μm or less, more preferably 1.0 μm or less, still more preferably 0.05 μm or less, and particularly preferably 0.01 to 0.02 μm.

By increasing the curvature radii of the first curved surface CS1 and the second curved surface CS2 in the side peripheral surface 10y to be more than the thickness of the electrode 13, the attachment of the charged foreign particles in a range more than the thickness of the electrode 13 in the side peripheral surface 10y can be suppressed. Therefore, micro discharge caused by the charged foreign particles in the side peripheral surface 10y can be suppressed, and dielectric breakdown in the side peripheral surface 10y can be suppressed.

### <<Method for Manufacturing Electrostatic Chuck Member>>

FIG. 4 is an explanatory view showing an example of the method for manufacturing the above-described electrostatic chuck member. The electrostatic chuck member 10 can be manufactured using a method including obtaining a disk-shaped sintered compact including the ceramic plates 11 and 12, the electrode 13, and the insulating layer 15 and where the first curved surface CS1 and the second curved surface CS2 are not processed (a step of obtaining the sintered compact); and grinding a side peripheral surface of the obtained sintered compact using a rotary grindstone (a grinding step).

At this time, in the rotary grindstone G to be used, a cross-section including a rotation axis L of the rotary grindstone G has a shape complementary to the shape of the first curved surface CS1, the shape of the second curved surface CS2, and the inclined surface 10a in the cross-section in the field of views of FIGS. 2 and 3. In the rotary grindstone G, a curvature radius of a portion corresponding to the first curved surface CS1 is r1 that is the same as the curvature radius of the first curved surface CS1. In addition, in the grindstone G, a curvature radius of a portion corresponding to the second curved surface CS2 is r2 that is the same as the curvature radius of the second curved surface CS2. By grinding a peripheral edge portion of the placement surface 10x using the rotary grindstone, the electrostatic chuck member 10 including the first curved surface CS1 and the second curved surface CS2 can be easily formed.

With the above-described manufacturing method, a fixing angle of the grindstone does not need to be changed depending on the curved surface to form the first curved surface CS1 and the second curved surface CS2, and the electrostatic chuck member including the first curved surface CS1 and the second curved surface CS2 can be easily manufactured. In addition, by accurately preparing the rotary grindstone G, the electrostatic chuck member 10 can be manufactured with high reproducibility.

In the above description, the rotary grindstone G has a shape complementary to the first curved surface CS1 and the second curved surface CS2, but a rotary grindstone having a shape complementary to at least a part of any one of the first curved surface CS1 or the second curved surface CS2 may be used for processing. In addition, by performing the processing using the above-described rotary grindstone, replacement or angle adjustment of the grindstone can be significantly reduced, and the production efficiency can be improved. In addition, a variation in manufacturing caused by the replacement or the angle adjustment of the grindstone can be suppressed.

In addition, the third curved surface CS3 can also be formed by grinding using a rotary grindstone, as in the first curved surface CS1 and the second curved surface CS2. Optionally, polishing finishing with a brush or a buff may be further performed.

With the electrostatic chuck member 10 having the above-described configuration, the problem (a decrease in productivity or dielectric breakdown) caused by the attachment of the charged foreign particles to the side peripheral surface 10y can be reduced.

In the present embodiment, the side peripheral surface 10y includes the two convex surfaces (the first curved surface CS1 and the second curved surface CS2), but the present invention is not limited thereto. In addition to the first curved surface CS1 as the convex surface that is provided in the circumferential direction in the peripheral edge portion of the placement surface 10x and the second curved surface CS2 that is provided in the circumferential direction at a different height position from the first curved surface CS1, the side peripheral surface 10y may be configured to further include a third curved surface, a fourth curved surface, and the like as convex surfaces that are provided in the circumferential direction at different height positions from the first curved surface CS1.

### Second Embodiment

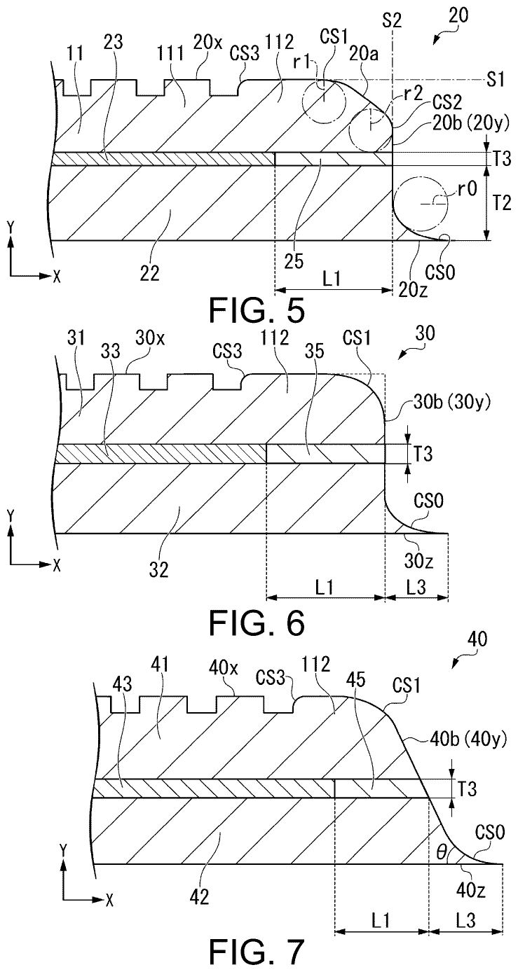

FIG. 5 is an explanatory view showing an electrostatic chuck member 20 according to a second embodiment. In each of the following embodiments, materials common to those of the electrostatic chuck member 10 according to the first embodiment can be used, and shapes are different. In each of the following embodiments, the components common to those of the first embodiment will not be described in detail.

As shown in FIG. 5, the electrostatic chuck member 20 includes a pair of ceramic plates 11 and 22, and an electrostatic adsorption electrode 23 and an insulating layer 25 interposed between the pair of ceramic plates 11 and 22. The configuration where the pair of ceramic plates 11 and 22 and the insulating layer 25 are combined corresponds to the substrate according to the present invention.

The ceramic plate 11 is the same as the ceramic plate including the above-described electrostatic chuck member 10. In an upper end portion of a side peripheral surface 20y of the electrostatic chuck member 20, the first curved surface CS1, an inclined surface 20a, and the second curved surface CS2 are formed as in the above-described electrostatic chuck member 10.

In addition, the side peripheral surface 20y includes a portion 20z extending outward in a lower end portion of the side peripheral surface 20y. An upper surface of the portion 20z is a concave surface CS0 that is provided in the circumferential direction of the electrostatic chuck member 20. That is, in the side peripheral surface 20y, the first curved surface CS1, the inclined surface 20a, and the second curved surface CS2 are formed on an upper end side, and the concave surface CS0 and a main surface 20b connecting the second curved surface CS2 and the concave surface CS0 are formed on a lower end side. The main surface 20b is a surface extending in the Y direction.

In the electrostatic chuck member 20, the first curved surface CS1 and the second curved surface CS2 may be formed in a part of the side peripheral surface 20y in the circumferential direction, or the first curved surface CS1 and the second curved surface CS2 may be formed in the entire area in the circumferential direction. In addition, the curvature of each of the first curved surface CS1 and the second curved surface CS2 may be fixed in the circumferential direction or may vary in the circumferential direction.

In addition, in the electrostatic chuck member 30, the concave surface CS0 may be formed in a part of a side peripheral surface 30y in the circumferential direction, or the concave surface CS0 may be formed in the entire area in the circumferential direction. In addition, the curvature radius of the concave surface CS0 may be fixed in the circumferential direction or may vary in the circumferential direction.

In general, it is known that plasma is difficult to reach a lower portion of the side peripheral surface of the electrostatic chuck member during plasma cleaning and, even when the charged foreign particles are attached to the lower portion, it is difficult to remove the charged foreign particles. On the other hand, in the electrostatic chuck member 20, the concave surface CS0 is formed on the lower end side of the side peripheral surface 20y, and is exposed to a field of view in a plan view. As a result, the plasma cleaning of the lower end side of the side peripheral surface 20y is facilitated. In addition, the charged foreign particles desorbed from the side peripheral surface 20y during the plasma cleaning fly out in the Y direction. Therefore, the charged foreign particles are not likely to float in the vicinity of the side peripheral surface 20y, and reattachment thereof is likely to be suppressed.

A curvature radius r0 of the concave surface CS0 is preferably equal to or more than the thickness T3 of the electrode 23.

It is preferable that the curvature radius r1 of the first curved surface CS1 and the curvature radius r0 of the concave surface CS0 have a relationship of the following Expression (1).

$$[ Curvature Radius r 1 of First Curved Surface CS 1 ] < [ Curvature Radius r 0 of Concave Surface CS 0 ] \qquad ( 1 )$$

It is preferable that the curvature radius r2 of the second curved surface CS2 and the curvature radius r0 of the concave surface CS0 have a relationship of the following Expression (2).

$$[ Curvature Radius r 2 of Second Curved Surface CS 2 ] < [ Curvature Radius r 0 of Concave Surface CS 0 ] \qquad ( 2 )$$

In the side peripheral surface of the typical electrostatic chuck member, abnormal discharge is likely to occur in a corner portion of the upper portion where a suction electric field concentrates such that the charged foreign particles concentrate in a narrow range and in a corner portion of the lower portion where shielding properties are high such that the charged foreign particles are likely to remain. In the electrostatic chuck member 20, by setting the corner portion of the upper portion as the first curved surface CS1 or the second curved surface CS2, and setting the corner portion of the lower portion as the concave surface CS0, deposition of the charged foreign particles is suppressed.

Here, in a case where the first curved surface CS1 and the second curved surface CS2 are formed to be large, the placement surface 20x is relatively narrowed, and the area of the plate-shaped sample that can be placed is reduced.

On the other hand, an electrostatic chuck member satisfying (1) and (2) is preferable since both the securing of the area of the placement surface 20x and the suppression of abnormal discharge are easily achieved.

In the concave surface CS0, an arithmetic average roughness Ra is preferably 2 μm or less. By setting the arithmetic average roughness Ra of the concave surface CS0 to be 2 μm or less, both of the effect obtained by the concave surface CS0 and the effect obtained by increasing the surface accuracy can be obtained, and the attachment of the charged foreign particles can be effectively suppressed. Similar to the above-described curved surface, the Ra of the concave surface CS0 is preferably 1.5 μm or less, more preferably 1.0 μm or less, still more preferably 0.05 μm or less, and particularly preferably 0.01 to 0.02 μm.

In a direction orthogonal to the normal direction of the placement surface 20x, a distance (width L3 of the portion 20z in the X direction) from the main surface 20b to an outward end portion of the concave surface CS0 is preferably equal to or more than the thickness T3 of the electrode 23.

Even with the electrostatic chuck member 20 having the above-described configuration, the concentration of the electrostatic field can be suppressed and the attachment of the charged foreign particles can be suppressed by the functions of the first curved surface, the second curved surface, and the third curved surface, and the problems (decrease in productivity and dielectric breakdown) caused by the attachment of the charged foreign particles to the side peripheral surface 20y can be reduced.

In the present embodiment, the main surface 20b is a surface parallel to the Y direction, but the present embodiment is not limited thereto. The main surface 20b may also be an inclined surface exposed to a field of view in a plan view.

### Third Embodiment

FIG. 6 is an explanatory view showing an electrostatic chuck member 30 according to a third embodiment. As shown in FIG. 6, the electrostatic chuck member 30 includes a pair of ceramic plates 31 and 32, and an electrostatic adsorption electrode 33 and an insulating layer 35 interposed between the pair of ceramic plates 31 and 32. The configuration where the pair of ceramic plates 31 and 32 and the insulating layer 35 are combined corresponds to the substrate according to the present invention.

In an upper end portion of a side peripheral surface 30y of the electrostatic chuck member 30, the first curved surface CS1 exposed to a field of view from the normal direction of a chamfered placement surface 30x is formed. The first curved surface CS1 is a convex surface.

In addition, in the electrostatic chuck member 30, the first curved surface CS1 may be formed in a part of a side peripheral surface 30y in the circumferential direction, or the first curved surface CS1 may be formed in the entire area in the circumferential direction. In addition, the curvature radius of the first curved surface CS1 may be fixed in the circumferential direction or may vary in the circumferential direction.

In addition, the side peripheral surface 30y includes a portion 30z extending outward in a lower end portion of the side peripheral surface 30y as in the electrostatic chuck member 20 according to the second embodiment. An upper surface of the portion 30z is a concave surface CS0 that is provided in the circumferential direction of the electrostatic chuck member 30. The concave surface CS0 corresponds to a “second curved surface” in the present invention.

It is preferable that the curvature radius r1 of the first curved surface CS1, the curvature radius r0 of the concave surface CS0, the thickness T3 of the electrode 33, and the thickness T2 of the ceramic plate 32 (the thickness of the substrate from a lower surface of the electrostatic adsorption electrode to a lower surface of the substrate) have the following Expression (3).

$$[ Thickness T 3 of Electrode 33 ] < [ Curvature Radius r 1 of First Curved Surface CS 1 ] < [ Curvature Radius r 0 of Concave Surface CS 0 ] < [ Thickness T 2 of Ceramic Plate 32 ] \qquad ( 3 )$$

First, as described above, it is preferable that [Curvature Radius r1 of First Curved Surface CS1]<[Curvature Radius r0 of Concave Surface CS0] is satisfied because the securing of the area of the placement surface 30x and the suppression of abnormal discharge are likely to be achieved simultaneously.

Next, in the electrostatic chuck member that satisfies [Thickness T3 of Electrode 33]<[Curvature Radius r1 of First Curved Surface CS1], an electric field concentrating on the corner of the upper portion of the side peripheral surface of the electrostatic chuck member in the related art (the electrostatic chuck member not including the first curved surface CS1) can be dispersed to be wider than the thickness of the electrode 33, and deposition of the charged foreign particles can be suppressed.

Further, the electrostatic chuck member that satisfies [Curvature Radius r0 of Concave Surface CS0]<[Thickness T2 of Ceramic Plate 32] is preferable because the area of the electrostatic chuck member in a plan view is prevented from excessively increasing, and chipping or cracking is not likely to occur in the ceramic plate 32.

It is preferable that the arithmetic average roughness Ra of the first curved surface CS1 and the concave surface CS0 is 2 μm or less. The Ra of the first curved surface CS1 and the concave surface CS0 is preferably 1.5 μm or less, more preferably 0.05 μm or less, and still more preferably 0.01 to 0.02 μm.

Even with the electrostatic chuck member 30 having the above-described configuration, it is possible to reduce the problems (decrease in productivity and dielectric breakdown) caused by the attachment of the charged foreign particles to the side peripheral surface 30y due to the functions of the first curved surface, the second curved surface, and the third curved surface.

In the present embodiment, a main surface 30b is a surface parallel to the Y direction, but the present embodiment is not limited thereto. The main surface may also be an inclined surface exposed to a field of view in a plan view.

FIG. 7 is an explanatory view showing an electrostatic chuck member 40 according to a modification example of the third embodiment. As shown in FIG. 7, the electrostatic chuck member 40 includes a pair of ceramic plates 41 and 42, and an electrostatic adsorption electrode 43 and an insulating layer 45 interposed between the pair of ceramic plates 41 and 42. The configuration where the pair of ceramic plates 41 and 42 and the insulating layer 45 are combined corresponds to the substrate according to the present invention.

A side peripheral surface 40y includes the first curved surface CS1 provided at an upper end and the concave surface CS0 provided at a lower end. The concave surface CS0 is provided in a portion 40z extending outward. A surface (main surface) 40b between the first curved surface CS1 and the concave surface CS0 is an inclined surface that is linearly continuous.

In the electrostatic chuck member 40, a part of a main surface 40b in the circumferential direction may be an inclined surface, or the entire area of the main surface 40b in the circumferential direction may be an inclined surface. In addition, an inclination angle θ of the main surface 40b may be fixed in the circumferential direction or may vary in the circumferential direction.

Even with the electrostatic chuck member 40 having the above-described configuration, the concentration of the electrostatic field can be suppressed and the attachment of the charged foreign particles can be suppressed by the functions of the first curved surface, the second curved surface, and the third curved surface, and the problems (decrease in productivity and dielectric breakdown) caused by the attachment of the charged foreign particles to the side peripheral surface 40y can be reduced.

### [Electrostatic Chuck Device]

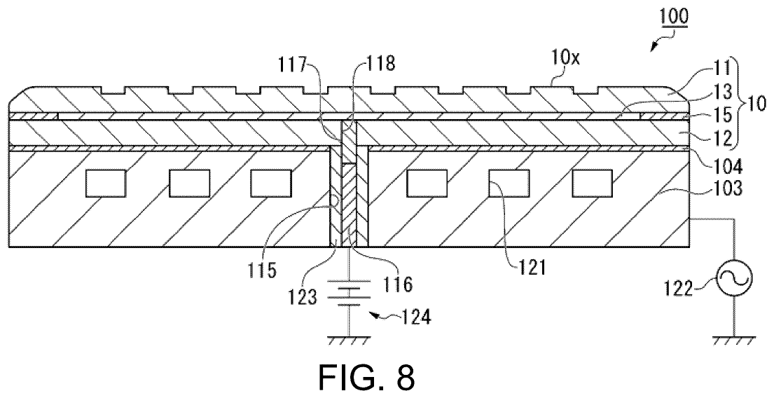

Hereinafter, an example of the electrostatic chuck device according to an embodiment of the present invention will be described with reference to FIG. 8. In the following description, the electrostatic chuck device including the electrostatic chuck member 10 described above will be described, but the other electrostatic chuck members described above can also be employed in the electrostatic chuck device. In each of the following embodiments, the components common to those of the first embodiment will be represented by the same reference numerals, and the detailed description will not be made.

FIG. 8 is a cross-sectional view showing an electrostatic chuck device according to the present embodiment. An electrostatic chuck device 100 includes the disk-shaped electrostatic chuck member 10, a disk-shaped base member 103 that cools the electrostatic chuck member 10 to adjust a temperature to a desired value, and an adhesive layer 104 that joins the electrostatic chuck member 10 and the base member 103 and integrates the electrostatic chuck member 10 and the base member 103.

In the following description, the electrostatic chuck member 10 side is referred to as “upper”, and the base member 103 side is referred to as “lower”, which may represent the relative positions of the respective configurations.

### [Electrostatic Chuck Member]

The electrostatic chuck member 10 has a power feeding terminal 116 provided in the fixing hole 115 of the base member 103 to be in contact with the electrode 13, in addition to the above-mentioned ceramic plates 11 and 12, the electrode 13, and the insulating layer 15.

### [Power Feeding Terminal]

The power feeding terminal 116 is a member that applies a voltage to the electrode 13.

The number, shape, and the like of the power feeding terminals 116 are determined depending on the form of the electrode 13, that is, whether the electrode 13 is unipolar or bipolar.

The material of the power feeding terminal 116 is not particularly limited as long as it is a conductive material having excellent heat resistance. As the material of the power feeding terminal 116, a material having a thermal expansion coefficient similar to those of the electrode 13 and the ceramic plate 12 is preferable. For example, a metal material such as a Kovar alloy or niobium (Nb) and various conductive ceramics are suitably used.

### [Conductive Adhesive Layer]

A conductive adhesive layer 117 is provided in the fixing hole 115 of the base member 103 and in a through-hole 118 of the ceramic plate 12. In addition, the conductive adhesive layer 117 is interposed between the electrode 13 and the power feeding terminal 116 and electrically connects the electrode 13 and the power feeding terminal 116 to each other.

A conductive adhesive forming the conductive adhesive layer 117 includes a conductive substance such as carbon fibers or metal powder and a resin.

The resin in the conductive adhesive is not particularly limited as long as it suppresses the occurrence of cohesive failure caused by thermal stress. Examples of the resin include a silicone resin, an acrylic resin, an epoxy resin, a phenol resin, a polyurethane resin, an unsaturated polyester resin, and the like.

Among these, a silicone resin is preferable from the viewpoints that the degree of expansion and contraction is high and cohesive failure caused by a change in thermal stress is not likely to occur.

### [Base Member]

The base member 103 is a disk-shaped thick member formed of at least one of a metal or a ceramic. The body of the base member 103 is configured to also function as an internal electrode for generating a plasma. In the body of the base member 103, a flow path 121 for circulating a coolant such as water, He gas, or N₂ gas is formed.

The body of the base member 103 is connected to an external high frequency power supply 122. In addition, in the fixing hole 115 of the base member 103, the power feeding terminal 116 of which the outer periphery is surrounded by an insulating material 123 is fixed through the insulating material 123. The power feeding terminal 116 is connected to an external direct current power supply 124.

A material forming the base member 103 is not particularly limited as long as it is a metal having excellent thermal conductivity, electrical conductivity, and workability or a compound material including the metal. As the material for forming the base member 103, for example, aluminum (A1), copper (Cu), stainless steel (SUS), titanium (Ti) is suitably used, or the like.

It is preferable that at least a surface of the base member 103 that is exposed to a plasma undergoes an alumite treatment or is coated with a resin such as a polyimide resin. In addition, it is more preferable that the entire surface of the base member 103 undergoes an alumite treatment or is coated with a resin as described above.

The base member 103 undergoes an alumite treatment or is coated with a resin such that plasma resistance of the base member 103 is improved and abnormal discharge is prevented. Accordingly, the plasma resistance stability of the base member 103 can be improved, and surface scratches of the base member 103 can also be prevented.

### [Adhesive Layer]

The adhesive layer 104 is configured to bond and integrate the electrostatic chuck member 10 and the base member 103.

The thickness of the adhesive layer 104 is preferably 100 μm or more and 200 μm or less and more preferably 130 μm or more and 170 μm or less.

When the thickness of the adhesive layer 104 is in the above-described range, the adhesion strength between the electrostatic chuck member 10 and the base member 103 can be sufficiently secured. In addition, the thermal conductivity between the electrostatic chuck member 10 and the base member 103 can be sufficiently secured.

A material of the adhesive layer 104 is formed of, for example, a cured product obtained by thermally curing a silicone resin composition, an acrylic resin, an epoxy resin, or the like.

The silicone resin composition is a silicon compound having a siloxane bond (Si—O—Si) and is a resin having excellent heat resistance and elasticity, which is more preferable.

As such a silicone resin composition, a silicone resin having a thermal curing temperature of 70° C. to 140° C. is particularly preferable.

Here, it is not preferable that the thermal curing temperature is lower than 70° C. because, when the electrostatic chuck member 10 and the base member 103 are joined in a state where they face each other, curing does not progress sufficiently in the process of joining such that the workability deteriorates. On the other hand, it is not preferable that the thermal curing temperature is higher than 140° C. because a difference in thermal expansion between the electrostatic chuck member 10 and the base member 103 is large and stress between the electrostatic chuck member 10 and the base member 103 increases, which may cause peeling therebetween.

That is, it is preferable that the thermal curing temperature is 70° C. or higher because the workability in the process of joining is excellent, and it is preferable that the thermal curing temperature is 140° C. or lower because the electrostatic chuck member 10 and the base member 103 are not likely to peel off from each other.

The electrostatic chuck device 100 according to the present embodiment includes the above-described electrostatic chuck member 10. Therefore, in the side peripheral surface of the electrostatic chuck member, the occurrence of dielectric breakdown (discharge) can be suppressed.

The electrostatic chuck device 100 may include a focus ring that surrounds the periphery of the electrostatic chuck member. In this case, the shape of the focus ring may be changed to a shape complementary to the shape of the side peripheral surface of the electrostatic chuck member.

### [Semiconductor Manufacturing Device]

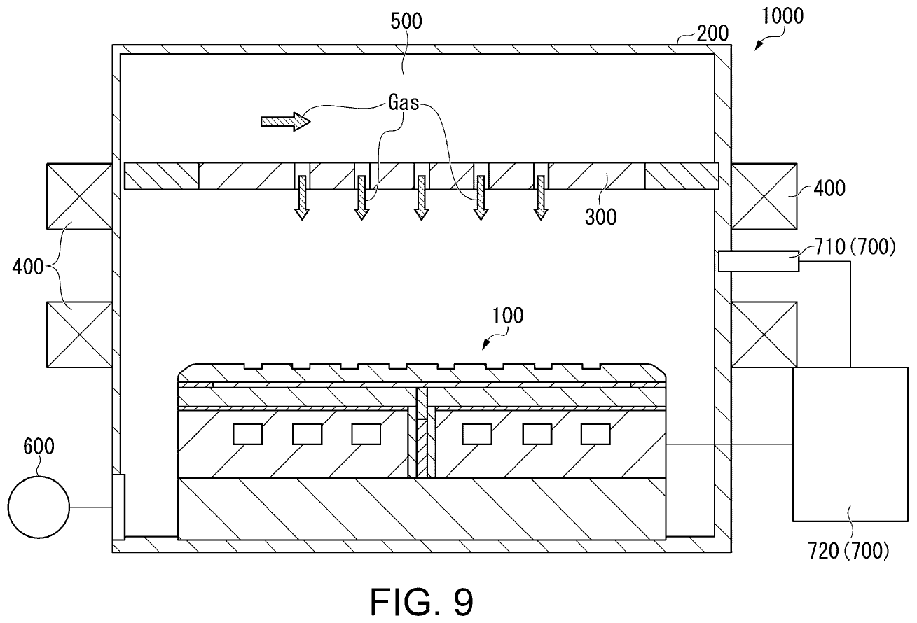

FIG. 9 is an explanatory view showing an example of a semiconductor manufacturing device having the above-described electrostatic chuck device. A semiconductor manufacturing device 1000 includes the electrostatic chuck device 100, a vacuum chamber 200, an upper electrode 300, a magnet 400, gas supply means 500, a vacuum pump 600, and a plasma stabilization system 700.

The vacuum chamber 200 accommodates the electrostatic chuck device 100 and is used as a reaction field where a plasma treatment is performed. The vacuum chamber 200 can adopt a well-known configuration used for a semiconductor manufacturing device. The vacuum chamber 200 includes a gate (not shown) into and from which the plate-shaped sample is put and taken out.

The upper electrode 300 is a counter electrode that is accommodated in the vacuum chamber 200 and is used together with the electrostatic chuck device 100 when a plasma is generated in the vacuum chamber 200. The upper electrode 300 is connected to a power supply (not shown).

The magnet 400 is disposed around the vacuum chamber 200 and generates a longitudinal magnetic field in a space between the upper electrode 300 and the electrostatic chuck device 100 in the vacuum chamber 200.

The gas supply means 500 supplies plasma gas Gas into the vacuum chamber 200. The gas supply means 500 supplies the plasma gas Gas into the vacuum chamber 200 from, for example, gas holes provided in the upper electrode 300.

The vacuum pump 600 exhausts gas in the vacuum chamber 200 and controls an atmosphere for generating a plasma. The vacuum pump 600 is connected to, for example, a region of the vacuum chamber 200 below the electrostatic chuck device 100.

The plasma stabilization system 700 detects various external factors for varying the state of the plasma in the semiconductor manufacturing device 1000, and compensates for the external factors to stabilize the state of the plasma. The plasma stabilization system 700 includes a detector 710, and a controller 720 that controls the semiconductor manufacturing device 1000 based on a detection result of the detector 710.

The detector 710 directly or indirectly detects the state of the plasma in the vacuum chamber 200. The number of the detectors 710 may be one or plural. Examples of items detected by the detector 710 include the degree of vacuum in the vacuum chamber 200, the color of the plasma, the temperature of the plasma, the capacitance between the upper electrode 300 and an internal electrode (not shown) for generating a plasma in the electrostatic chuck device 100, and the inductance between the upper electrode 300 and the internal electrode for generating a plasma.

The controller 720 controls the semiconductor manufacturing device 1000 based on a detection value of each of the items detected by the detector 710 or the amount of change in the detection value per unit time. The controller 720 prestores a correspondence between the detection values of the above-described items and the state of the plasma generated in the vacuum chamber 200. The controller 720 performs feedback control on the semiconductor manufacturing device 1000 such that the state of the plasma is within a predetermined range based on the detection values and the above-described correspondence. Examples of the items on which the feedback control is performed include the temperature, the degree of vacuum, and the bias voltage in the semiconductor manufacturing device.

Due to these items, the plasma stabilization system 700 can suppress a long-term variation in the plasma state of the semiconductor manufacturing device 1000 to stabilize the state.

The plasma stabilization system is effective for suppressing the long-term variation in the plasma state of the entire manufacturing process using the semiconductor manufacturing device. On the other hand, the plasma stabilization system is not effective for suppressing the stage variation for a variation factor that occurs within a very short period of time, for example, abnormal discharge during wafer processing.

On the other hand, since the semiconductor manufacturing device 1000 includes the above-described electrostatic chuck device 100, the wafer can suppress abnormal discharge that occurs during processing. Therefore, the semiconductor manufacturing device 1000 includes the plasma stabilization system 700, and thus can stabilize a plasma not only in a long-term perspective but also in a short-term perspective.

The controller 720 may be a unique configuration of the plasma stabilization system 700, or a control device that controls the semiconductor manufacturing device 1000 may also function as the controller 720.

In the semiconductor manufacturing device 1000, for example, the tendency of the attachment of the charged foreign particle to the side peripheral surface of the electrostatic chuck member 10 may vary depending on a position of an exhaust port of the vacuum chamber 200 (connection position of the vacuum pump 600). When the above-described tendency is empirically determined in the semiconductor manufacturing device 1000, the electrostatic chuck member 10 may adopt the configuration where the attachment of the charged foreign particles is suppressed, for example, the arithmetic average roughness Ra of a side peripheral surface at a position where the charged foreign particles are likely to be attached is less than that of other side peripheral surfaces.

The semiconductor manufacturing device 1000 according to the present embodiment includes the above-described electrostatic chuck device 100, and thus can suppress the occurrence of dielectric breakdown (discharge).

In addition, in the semiconductor manufacturing device 1000, abnormal discharge (the short-term variation in plasma) can be suppressed by the electrostatic chuck device 100, and the long-term variation in plasma can be suppressed by the plasma stabilization system 700. Therefore, a stable plasma treatment can be performed, and a semiconductor manufacturing device with an improved yield can be obtained.

The preferred embodiment of the present invention has been described above with reference to the accompanying drawings. However, the present invention is not limited to such an example. The various shapes, combinations, and the like of the constituent members shown in the above examples are merely examples, and various modifications can be made based on design requirements and the like without departing from the gist of the present invention. For example, omission, addition, change, replacement, exchange, and other changes are possible for materials, positions, ratios, amounts, types, numbers, sizes, values, and the like. In the embodiments, preferred conditions or examples may be exchanged or shared with each other.

In addition, although the silicon wafer has been described in the above description, it is clear that the wafer that can be treated with the electrostatic chuck member according to the embodiment of the present invention may be not only silicon but also indium phosphide, gallium arsenide, or other materials.

### INDUSTRIAL APPLICABILITY

The present invention provides an electrostatic chuck member capable of reducing a problem caused by the attachment of charged foreign particles to a side surface, particularly abnormal discharge occurring during a wafer processing. In addition, there is provided an electrostatic chuck device including the electrostatic chuck member.

### REFERENCE SIGNS LIST

10, 20, 30, 40, 50 Electrostatic chuck member
10a, 20a Inclined surface
10x, 20x, 30x Placement surface
10y, 20y, 30y, 40y Side peripheral surface
11, 12, 22, 31, 32, 41, 42 Ceramic plate
11x Space
11y Bottom portion
13, 23, 33, 43 Electrode (electrostatic adsorption electrode)
13x Outer edge
15, 25, 35, 45 Insulating layer
20b, 30b, 40b Main surface
20z, 30z, 40z Portion
100 Electrostatic chuck device
103 Base member
103a Upper surface
104 Adhesive layer
111 Micro protrusion
112 Annular protrusion
115 Fixing hole
116 Power feeding terminal
117 Conductive adhesive layer
118 Through-hole
121 Flow path
122 High frequency power supply
123 Insulating material
123 Direct current power supply
200 Vacuum chamber
300 Upper electrode
400 Magnet
500 Gas supply means
600 Vacuum pump
700 Plasma stabilization system
710 Detector
720 Controller
1000 Semiconductor manufacturing device
C Center
CS1 First curved surface
CS0 Concave surface
CS2 Second curved surface
CS3 Third curved surface
G Rotary magnet
L Rotation axis
L1, L2, L3 Width
H Height
M Center in width direction
N Normal line
r1, r2, r3, r0 Curvature radius
S, S1, S2 Virtual plane
T1, T2, T3 Thickness
W1, W2, W3 Distance
θ Inclination angle

1. An electrostatic chuck member comprising:
a substrate of which one main surface is a placement surface on which a plate-shaped sample is placed; and
an electrostatic adsorption electrode provided on a side opposite to the placement surface or in the substrate,
wherein a side peripheral surface that is continuous with the placement surface in the substrate includes at least a first curved surface that is a convex surface provided in a circumferential direction in a peripheral edge portion of the placement surface and a second curved surface provided in the circumferential direction at a different height position from the first curved surface,
the substrate has an annular protrusion provided along the peripheral edge portion of the placement surface,
an outer edge of the electrostatic adsorption electrode overlaps the annular protrusion in a plan view,
at least a part of the first curved surface is provided on an outer peripheral side of the annular protrusion, and
a third curved surface that is a convex surface provided in a circumferential direction of an inner periphery is provided on an inner peripheral side of the annular protrusion.

2. The electrostatic chuck member according to claim 1,
wherein, in a plan view, the outer edge is positioned closer to the outer peripheral side with respect to a center of the annular protrusion in a width direction, and
a curvature radius of the first curved surface is larger than a curvature radius of the third curved surface.

3. The electrostatic chuck member according to claim 2,
wherein the first curved surface is provided to extend from the annular protrusion to a portion of the substrate below the annular protrusion.

4. The electrostatic chuck member according to claim 1,
wherein the electrostatic chuck member satisfies following Expressions (A1) and (A2),
$$[ Thickness of Electrostatic Adsorption Electrode ] \leq [ Curvature Radius of First Curved Surface ] \qquad ( A1 )$$
$$[ Thickness of Electrostatic Adsorption Electrode ] \leq [ Curvature Radius of Third Curved Surface ] . \qquad ( A2 )$$

5. The electrostatic chuck member according to claim 1,
wherein a distance from the outer edge to the side peripheral surface is equal to or greater than a distance from an upper surface of the electrostatic adsorption electrode to the placement surface.

6. The electrostatic chuck member according to claim 2,
wherein a distance from the outer edge to the side peripheral surface is equal to or greater than a distance from an upper surface of the electrostatic adsorption electrode to the placement surface.

7. An electrostatic chuck device comprising:
the electrostatic chuck member according to any one of claim 1; and
a base member that cools the electrostatic chuck member to adjust a temperature of the electrostatic chuck member.
